(19) United States
(12) Patent Application Publication
(10) Pub. No.: US 2024/0429930 A1
(43) Pub. Date: Dec. 26, 2024

(54) ANALOG-TO-DIGITAL CONVERSION USING DIFFERENTIAL OSCILLATOR TECHNIQUES

(71) Applicant: Intel Corporation, Santa Clara, CA (US)

(72) Inventors: Sami Hyvonen, Beaverton, OR (US); Michael Lopez, Chandler, AZ (US); Zachary Brantner, Hillsboro, OR (US)

(21) Appl. No.: 18/213,424

(22) Filed: Jun. 23, 2023

(51) Int. Cl. H03M 1/10; H03K 3/03

(52) U.S. Cl. CPC H03M 1/1014; H03K 3/0315

(57) ABSTRACT

An apparatus includes a pair of voltage-controlled oscillators (VCOs). The pair includes a first VCO with a first biasing stage receiving an input voltage signal and a first output stage coupled to the first biasing stage. The first output stage generates a first output frequency signal based on the input voltage signal. The pair also includes a second VCO. The second VCO includes a second biasing stage receiving the input voltage signal and a second output stage coupled to the second biasing stage. The second output stage generates a second output frequency signal based on the input voltage signal.

### TECHNICAL FIELD

Embodiments pertain to techniques for analog-to-digital conversion using differential oscillator techniques.

### BACKGROUND

Measurement of analog voltages is desirable for debug of analog circuits. However, high-volume testing uses digital measurements that can be read through a test access port (TAP) or a scan chain, and obtaining such digital measurements based on analog voltages can be challenging.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a diagram of an analog-to-digital converter (ADC) using differential oscillator techniques, in accordance with some embodiments;

FIG. 2 illustrates graphs of input voltage versus output frequency for the oscillators in the ADC of FIG. 1, in accordance with some embodiments;

FIG. 3 is a diagram of measuring equipment using an ADC and a signal selection multiplexer for calibration and measurement, in accordance with some embodiments;

FIG. 4 is a diagram of an ADC using differential oscillator techniques, in accordance with some embodiments;

FIG. 5 is a diagram of an inverter stage used in the ADC of FIG. 4, in accordance with some embodiments;

FIG. 6 is a graph of input voltage versus output frequency for the two oscillators used in the ADC of FIG. 4, in accordance with some embodiments;

FIG. 7 is a graph of the differential frequency for the two oscillators used in the ADC of FIG. 4, in accordance with some embodiments;

FIG. 8 is a graph of frequency (F)-to-voltage (V) measurement error associated with the two oscillators used in the ADC of FIG. 6, in accordance with some embodiments;

FIG. 9 is a flow diagram of an example method for analog-to-digital conversion, in accordance with some embodiments; and

FIG. 10 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for, those of other embodiments. Embodiments outlined in the claims encompass all available equivalents of those claims.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, materials, insulator thicknesses, and gate(s) configurations, to mention just a few. Moreover, unless specifically referred to as MOS, TFET, CFET, or other, the term transistor can encompass other suitable transistor types, e.g., junction-field-effect transistors, bipolar-junction transistors, metal-semiconductor FETs, and various types of three-dimensional transistors, known today or not yet developed.

The term “channel” refers to a transmission path through which a signal (X(t) in the depicted figure) propagates from a transmitter output to a receiver input. It may include combinations of conductive traces, wireless paths, and/or optical transmission media. For example, it could include combinations of packaging components (e.g., bond wires, solder balls), package traces, sockets, printed-circuit board (PCB) traces, cables (e.g., coaxial, ribbon, twisted pair), waveguides, air (and any other wireless transmission media), optical cable (and other optical transmission components), and so on. It may also include higher-level components for driving, routing, and/or switching signals onto or off of the channel.

As used herein, the term “chip” (or die) refers to a piece of a material, such as a semiconductor material, that includes a circuit such as an integrated circuit or a part of an integrated circuit.

The term memory IP indicates memory intellectual property. The terms memory IP, memory device, memory chip, and memory are interchangeable. A chipset is an integrated circuit block that has been designed to work with other chipsets to form larger more complex processing modules. In such modules, a system is subdivided into circuit blocks, called “chipsets”, that are often made of reusable IP blocks. They typically are formed on a single semiconductor die but may comprise multiple dies or die components. A benefit of employing chipsets to make a processing module is that they may be formed from different process nodes with different associated strengths, costs, etc. In addition, in many cases, it is easier to make smaller chipsets forming a larger, overall processing system rather than implementing the system on a single die.

In some aspects, measurement equipment can use an ADC to convert analog voltage into a digital number (e.g., a 10-bit value). This digital output can be read out through a TAP or a scan chain. Alternatively, a voltage-controlled oscillator (VCO) and a counter can be used to translate the analog measurement into a digital value. The analog voltage can be used as a bias to the VCO, which then oscillates at a frequency corresponding to the analog bias. A counter counts the cycles of the oscillator output for a fixed amount of time, to determine the oscillation frequency. In post-processing, the frequency can be translated into an analog voltage, using data from previously-performed calibration steps.

The main drawback of using an ADC is its size. For example, a micro Sigma-Delta ADC used for measuring analog outputs can be larger than the analog circuit under test.

Compared to a ADC, a VCO can be very small. However, oscillators (e.g., ring oscillators) can be difficult to design to cover the full voltage range from voltage supply source (Vss) voltage (e.g., 0 V) to voltage common collector (Vcc) voltage. In some aspects, a ring oscillator can include either an NMOS or a PMOS-based bias circuitry, limiting the functional voltage range to about ¾ of the full Vss-to-Vcc voltage range. Moreover, as the voltage being measured gets closer to the edge of the functional range of the oscillator, the oscillator slows down significantly, requiring a longer fixed measurement time for the same accuracy or resolution.

In some embodiments, an ADC can be configured based on differential oscillator techniques using at least two voltage-controlled oscillators (VCOs) (or current-controlled oscillators) with each oscillator covering at least one-half of the input voltage range. In some aspects, the at least two oscillators can be ring oscillators, LC oscillators, relaxation oscillators, or any other controlled oscillator (including any voltage- or current-controlled oscillators), which are configured to collectively cover an entire input signal range. In some aspects, each of the oscillators in the ADC can be designed and optimized independently. In some aspects, the differential oscillator techniques use two ring oscillators—one using NMOS-based biasing and the other using PMOS-based biasing—with both oscillators used for every measurement. The difference between the two output frequencies from both oscillators can be used to determine the measured voltage.

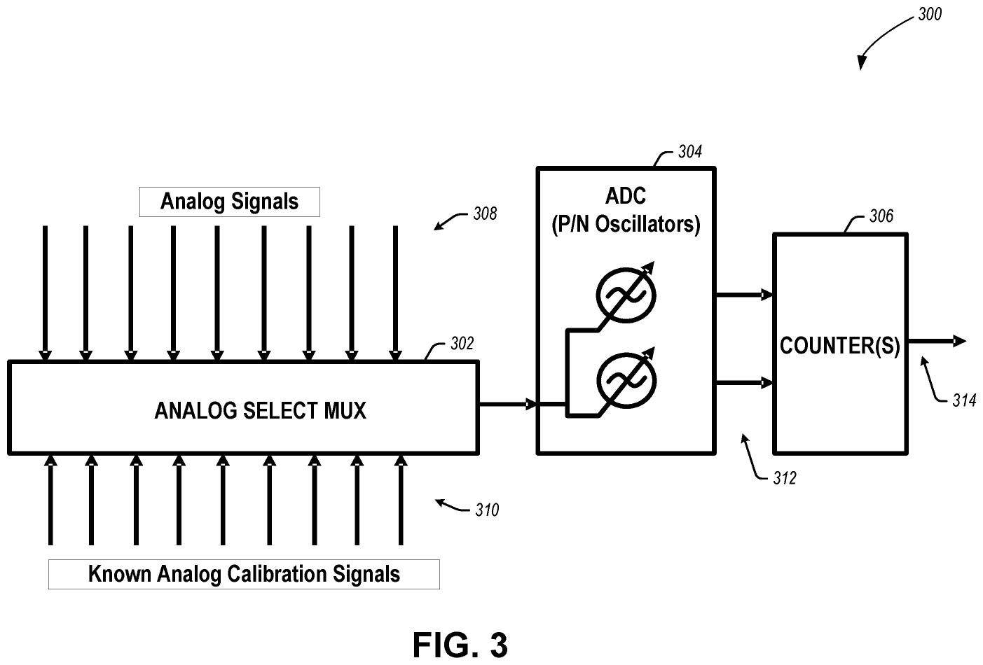

An advantage of the disclosed differential oscillator techniques in comparison to techniques using a single ring oscillator is that speed and accuracy are maintained across the full voltage range (e.g., as explained below in connection with FIG. 3-FIG. 8). For example, if measuring a voltage close to Vss, the NMOS-based oscillator is not oscillating but the PMOS-based oscillator is oscillating, providing accurate output data. Conversely, for measuring voltages close to Vcc, the PMOS-based oscillator is not oscillating but the NMOS-based oscillator is. In the middle of the voltage range for the input voltage signal, both are oscillating. Compared to an ADC-based solution, the two-oscillator solution disclosed herein is significantly smaller than the ADC, with similar accuracy.

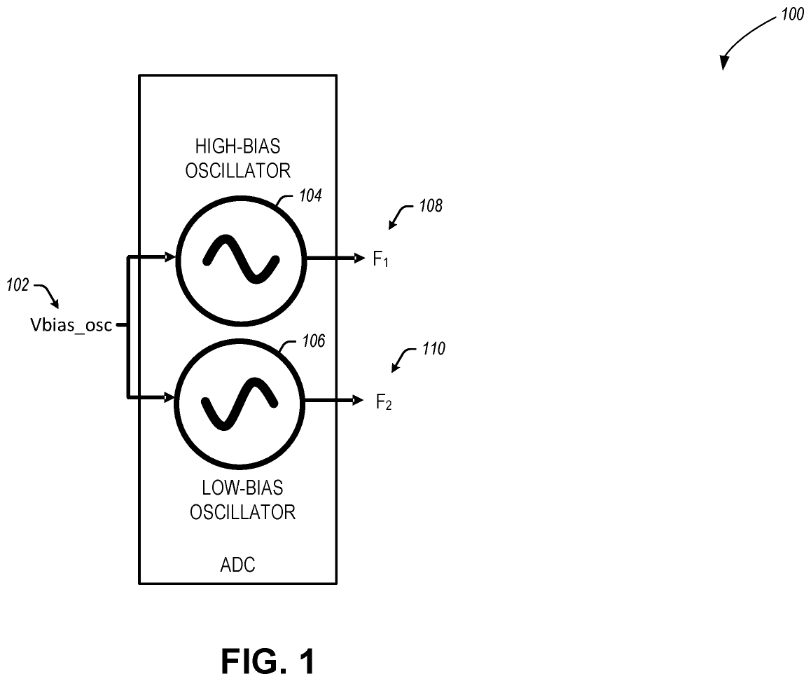

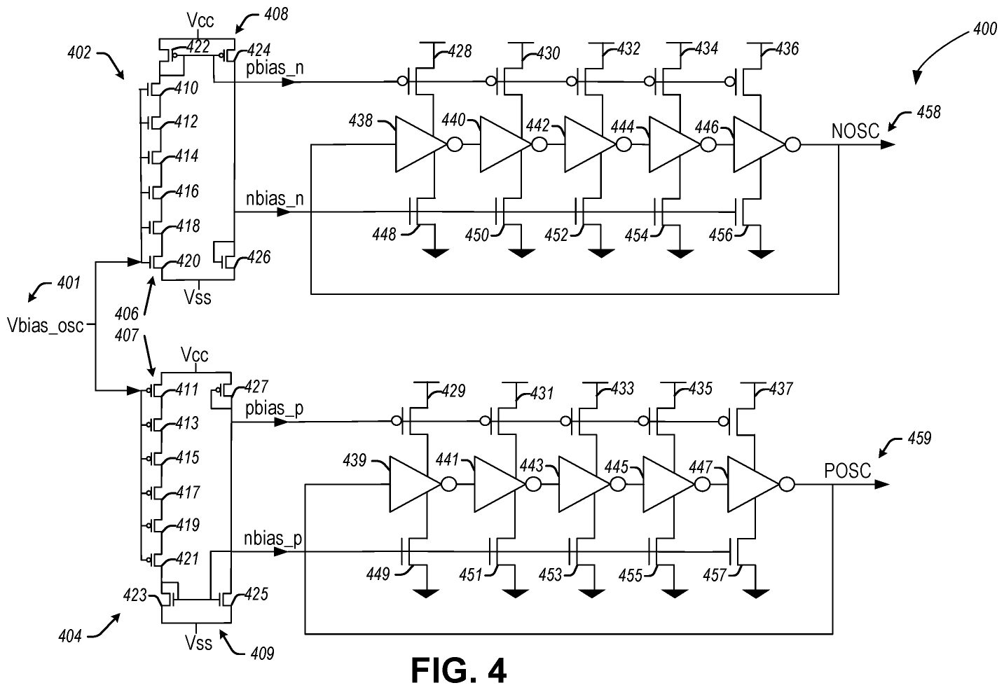

FIG. 1 is a diagram of an analog-to-digital converter (ADC) 100 using differential oscillator techniques, in accordance with some embodiments. Referring to FIG. 1, ADC 100 is configured to operate according to the disclosed differential oscillator techniques. More specifically, ADC 100 includes a VCO 104 configured to operate as a high-bias oscillator (e.g., as a PMOS oscillator) and VCO 106 configured to operate as a low-bias oscillator (e.g., an NMOS oscillator). VCOs 104 and 106 both receive an input voltage signal 102 (also referred to as Vbias_osc) and generate corresponding output frequency signals 108 (or F1) and 110 (or F2). An example implementation of ADC 100 using ring oscillators configured according to differential oscillator techniques is illustrated in FIG. 4.

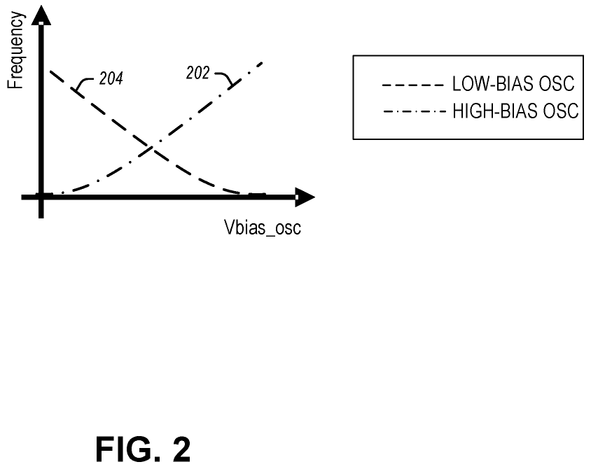

FIG. 2 illustrates graphs 202 and 204 of input voltage versus output frequency for the oscillators in the ADC of FIG. 1, in accordance with some embodiments. As seen in FIG. 2, each of VCOs 104 and 106 can be configured to cover at least half of the operating range of the input voltage signal 102. More specifically, graph 202 illustrates that the high-bias oscillator (e.g., VCO 104) is not operating in lower ranges of the input voltage signal and is operating in the higher ranges of the input voltage signal. Similarly, graph 204 illustrates that the low-bias oscillator (e.g., VCO 106) is operating in lower ranges of the input voltage signal and is not operating in the higher ranges of the input voltage signal. Graphs 202 and 204 also illustrate that both VCOs 104 and 106 operate in the mid-ranges of the input voltage signal.

FIG. 3 is a diagram of measuring equipment using an ADC and a signal selection multiplexer for calibration and measurement, in accordance with some embodiments. Referring to FIG. 3, measuring equipment 300 includes a multiplexer 302, an ADC 304, and at least one counter 306.

In some embodiments, multiplexer 302 receives one or more analog signals 308 (e.g., input voltage signals from one or more transistor-based devices).

ADC 304 can be configured according to the disclosed differential oscillator techniques (e.g., as illustrated in FIG. 3). For example, ADC 304 includes at least two oscillators generating at least one output frequency signal 312 based on an input voltage signal received from the multiplexer 302 and based on the one or more analog signals 308. The at least one counter 306 can generate a digital output 314 (e.g., at least one count value) based on oscillations of the at least one output frequency signal 312.

In some embodiments, multiplexer 302 also receives known analog calibration signals 310 which can be used to calibrate ADC 304 and the generation of the at least one output frequency signal 312 and the digital output 314.

FIG. 4 is a diagram of an ADC using differential oscillator techniques, in accordance with some embodiments. Referring to FIG. 4, ADC 400 comprises at least two oscillators, such as oscillator 402 and oscillator 404. In some embodiments, oscillators 402 and 404 are voltage-controlled oscillators, each covering at least half of the voltage range of the input voltage signal 401.

In some embodiments, oscillators 402 and 404 can be configured as ring oscillators, LC oscillators, relaxation oscillators, or any other controlled oscillator (including any voltage- or current-controlled oscillators). Collectively, the oscillators are configured to cover the entire voltage range of the input voltage signal.

In the particular example embodiment illustrated in FIG. 4, oscillator 402 is an NMOS-based oscillator (also referenced as NOSC) and oscillator 404 is a PMOS-based oscillator (also referred to as POSC).

Oscillator 402 includes a biasing circuit with an input stage 406 and a mirroring stage 408. The input stage 406 includes a plurality of serially coupled N-type metal-oxide semiconductor (NMOS) transistors (e.g., NMOS transistors 410, 412, 414, 416, 418, and 420). The plurality of NMOS transistors 410, 412, 414, 416, 418, and 420 include a corresponding plurality of gate terminals configured to receive an input voltage signal 401 (also referenced as Vbias_osc).

The mirroring stage 408 includes a plurality of P-type metal-oxide semiconductor (PMOS) transistors (e.g., PMOS transistors 422 and 424). The PMOS transistors 422 and 424 have corresponding source terminals coupled to a voltage common collector (Vcc) rail and are configured to generate PMOS bias voltage pbias_n based on the input voltage signal 401. The biasing circuit of oscillator 402 also includes NMOS transistor 426 coupled to the input stage 406 and configured to generate NMOS bias voltage nbias_n.

Oscillator 404 includes a biasing circuit with an input stage 407 and a mirroring stage 409. The input stage 407 includes a plurality of serially coupled PMOS transistors (e.g., PMOS transistors 411, 413, 415, 417, 419, and 421). The plurality of PMOS transistors 411, 413, 415, 417, 419, and 421 include a corresponding plurality of gate terminals configured to receive the input voltage signal 401 (also referenced as Vbias_osc).

The mirroring stage 409 includes a plurality of NMOS transistors (e.g., NMOS transistors 423 and 425). The NMOS transistors 423 and 425 have corresponding drain terminals coupled to a voltage supply source (Vss) rail and are configured to generate NMOS bias voltage nbias_p based on the input voltage signal 401. The biasing circuit of oscillator 404 also includes PMOS transistor 427 coupled to the input stage 407 and configured to generate PMOS bias voltage pbias_p.

Oscillator 402 further includes a plurality of inverter stages, such as a first inverter stage (e.g., formed by a PMOS transistor 428 coupled to a supply pin of inverter 438 and an NMOS transistor 448 coupled to a ground pin of inverter 438), a second inverter stage (e.g., formed by a PMOS transistor 430 coupled to a supply pin of inverter 440 and an NMOS transistor 450 coupled to a ground pin of inverter 440), a third inverter stage (e.g., formed by a PMOS transistor 432 coupled to a supply pin of inverter 442 and an NMOS transistor 452 coupled to a ground pin of inverter 442), a fourth inverter stage (e.g., formed by a PMOS transistor 434 coupled to a supply pin of inverter 444 and an NMOS transistor 454 coupled to a ground pin of inverter 444), and a fifth inverter stage (e.g., formed by a PMOS transistor 436 coupled to a supply pin of inverter 446 and an NMOS transistor 456 coupled to a ground pin of inverter 446). Inverter 446 generates the output frequency signal 458 of oscillator 402 based on the input voltage signal 401.

Oscillator 404 further includes a plurality of inverter stages, such as a first inverter stage (e.g., formed by a PMOS transistor 429 coupled to a supply pin of inverter 439 and an NMOS transistor 449 coupled to a ground pin of inverter 439), a second inverter stage (e.g., formed by a PMOS transistor 431 coupled to a supply pin of inverter 441 and an NMOS transistor 451 coupled to a ground pin of inverter 441), a third inverter stage (e.g., formed by a PMOS transistor 433 coupled to a supply pin of inverter 443 and an NMOS transistor 453 coupled to a ground pin of inverter 443), a fourth inverter stage (e.g., formed by a PMOS transistor 435 coupled to a supply pin of inverter 445 and an NMOS transistor 455 coupled to a ground pin of inverter 445), and a fifth inverter stage (e.g., formed by a PMOS transistor 437 coupled to a supply pin of inverter 447 and an NMOS transistor 457 coupled to a ground pin of inverter 447). Inverter 447 generates the output frequency signal 459 of oscillator 404 based on the input voltage signal 401.

In some aspects, PMOS transistors 428, 430, 432, 434, and 436 are biased by bias voltage pbias_n, and NMOS transistors 448, 450, 452, 454, and 456 are biased by bias voltage nbias_n.

In some aspects, PMOS transistors 429, 431, 433, 435, and 437 are biased by bias voltage pbias_p, and NMOS transistors 449, 451, 453, 455, and 457 are biased by bias voltage nbias_p.

Bias voltages pbias_n, pbias_p, nbias_n, and nbias_p determine how “strong” these extra PMOS and NMOS transistors are, affecting how much current is going into the inverter stage from the supply (e.g., the biasing circuit including the input stage and the mirroring stage), and how much is coming out and flowing to ground.

In some aspects, if Vbias_osc is close to Vss (e.g., within a threshold voltage from Vss), it is below the threshold voltage of the bias NMOS device, so the bias is essentially turned OFF and the NOSC does not oscillate. Similarly, if Vbias_osc is close to Vcc, the POSC does not oscillate.

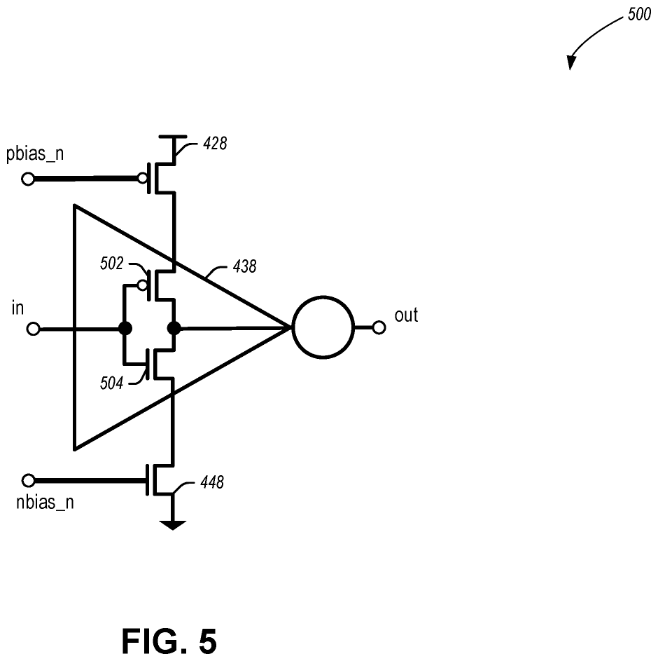

FIG. 5 is a diagram of an inverter stage used in the ADC of FIG. 4, in accordance with some embodiments. Referring to FIG. 5, inverter stage 500 is illustrated as the first inverter stage of oscillator 402 in FIG. 4. As illustrated in FIG. 5, inverter stage 400 includes the PMOS transistor 428 coupled to a supply pin of inverter 438, and the NMOS transistor 448 coupled to a ground pin of inverter 438. In some aspects, inverter 438 includes a PMOS transistor 502 and an NMOS transistor 504. The gate terminals of transistors 502 and 504 are coupled to the input terminal of inverter 438. The output terminal of inverter 438 is coupled to a drain terminal of transistor 502 and a source terminal of transistor 504.

In some aspects, the remaining inverters in FIG. 4 can be configured similarly to inverter 438 illustrated in FIG. 5.

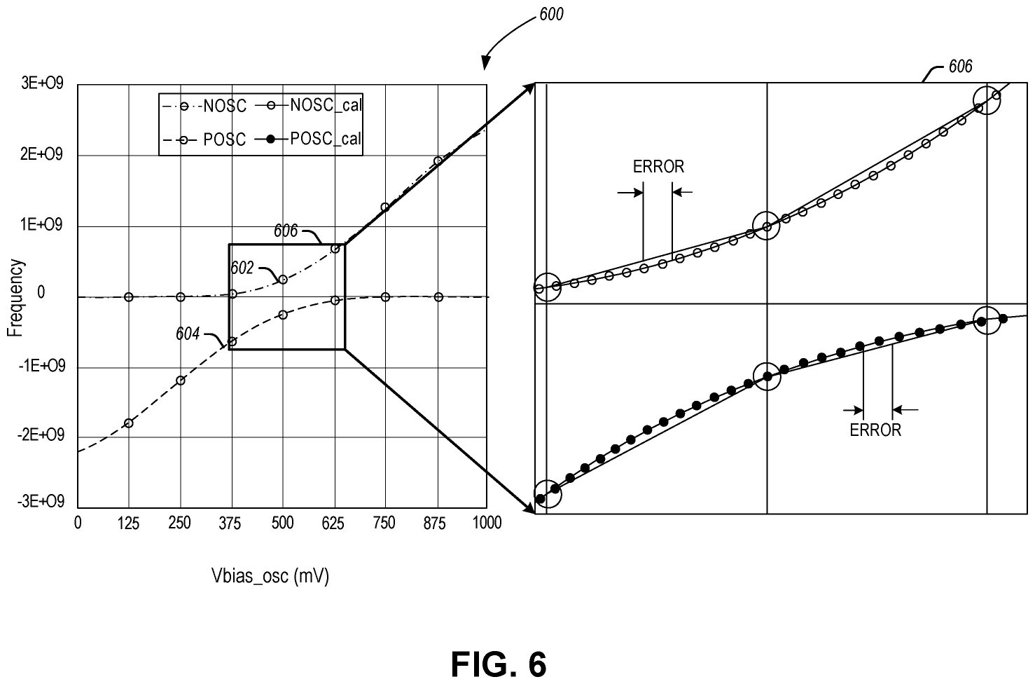

FIG. 6 is graph 600 of input voltage versus output frequency for the two oscillators used in the ADC of FIG. 4, in accordance with some embodiments. Graph 600 is based on measured data from a test chip. The oscillation frequencies of the NMOS and PMOS oscillators are plotted (e.g., graphs 602 and 604) with Vbias_osc being swept from 0V (=Vss) to 1V (=Vcc). Note that PMOS frequencies are shown as negative values for clarity.

FIG. 6 also shows magnified section 606 associated with the mid-range of the input voltage signal, with the magnified section 606 showing the calibration points for the two oscillators (e.g., NOSC and POSC of FIG. 4). This implementation employs an 8-segment Piece-Wise Linear (PWL) calibration method, where nine known calibration voltages (e.g., seven outputs of an 8-resistor ladder DAC, along with Vss and Vcc) are multiplexed into the oscillator inputs, and output frequencies are measured. In some aspects, when the voltages are measured, linear models are used in the voltage/frequency segments between the calibration points. Magnified section 606 in FIG. 6 also shows qualitatively how there is an error between the linear model and the actual oscillation frequencies.

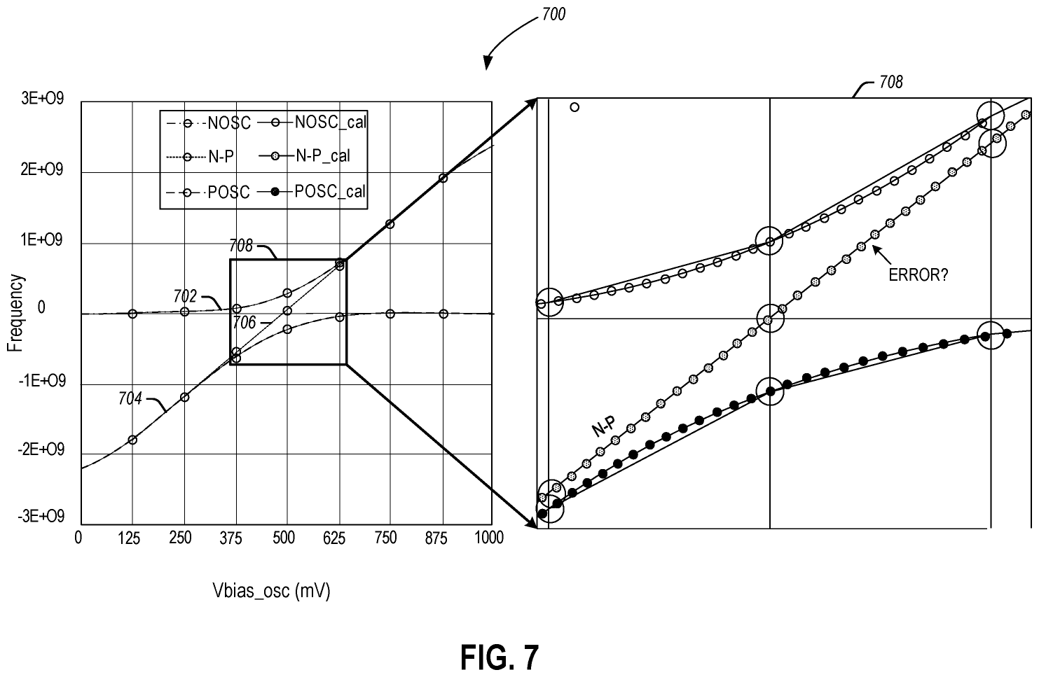

FIG. 7 is a graph 700 of the differential frequency for the two oscillators used in the ADC of FIG. 4, in accordance with some embodiments. Referring to FIG. 7, the oscillation frequencies of the NMOS and PMOS oscillators are plotted (e.g., graphs 702 and 704) with Vbias_osc being swept from 0V (=Vss) to 1V (=Vcc).

If a difference of the oscillation frequencies is calculated (Fdiff=Fnosc−Fposc) (which is represented by graph 706 visible in magnified section 708), the resulting V-to-F curve looks very linear (this “differential frequency” is shown in FIG. 7). Qualitatively, it can be difficult to see any error between the linear model and the actual differential frequency.

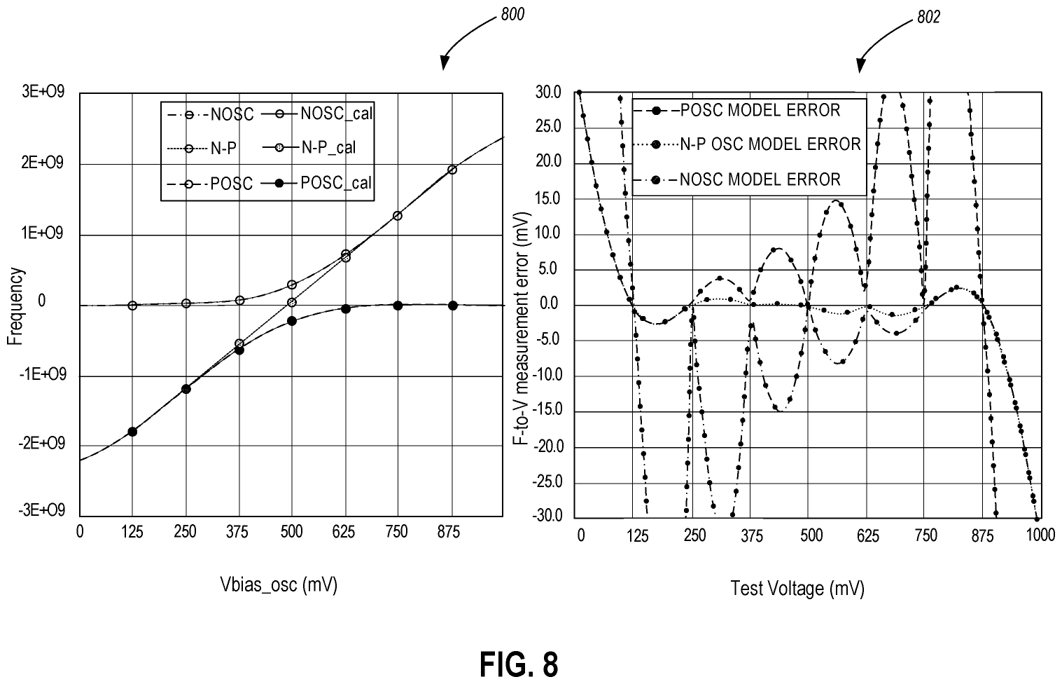

FIG. 8 is a graph 800 of input voltage signal (V) versus output frequency (F) and graph 802 of frequency (F)-to-voltage (V) measurement error associated with the two oscillators used in the ADC of FIG. 4, in accordance with some embodiments;

The effectiveness of the disclosed differential oscillator techniques is demonstrated in FIG. 8. The right-side plot shows the error between the PWL models and actual data, comparing errors of individual NMOS and PMOS oscillators to the error using the differential method. The error in individual oscillators can go beyond 30 mV, while with the differential oscillator techniques method the error is very close to zero across most of the measurement range (125-875 mV), peaking at 3 mV.

The disclosed differential oscillator techniques can be applied for analog-to-digital conversion without a requirement to match the two oscillators, except that the voltage ranges have to have some overlap; i.e., both oscillators can oscillate in the middle of the measurement voltage range. In some aspects, the impact of random variations in the oscillator transistors is negligible (these change the F-V curve of the individual oscillators slightly). PWL calibration and differential method “calibrate out” these effects. Insensitivity to random variation means the oscillators can be made very small and simple.

In some aspects, when the measurements (and calibration steps) are done using the two complementary oscillators, the differential data analysis can be done through post-processing, without the need to include additional silicon hardware.

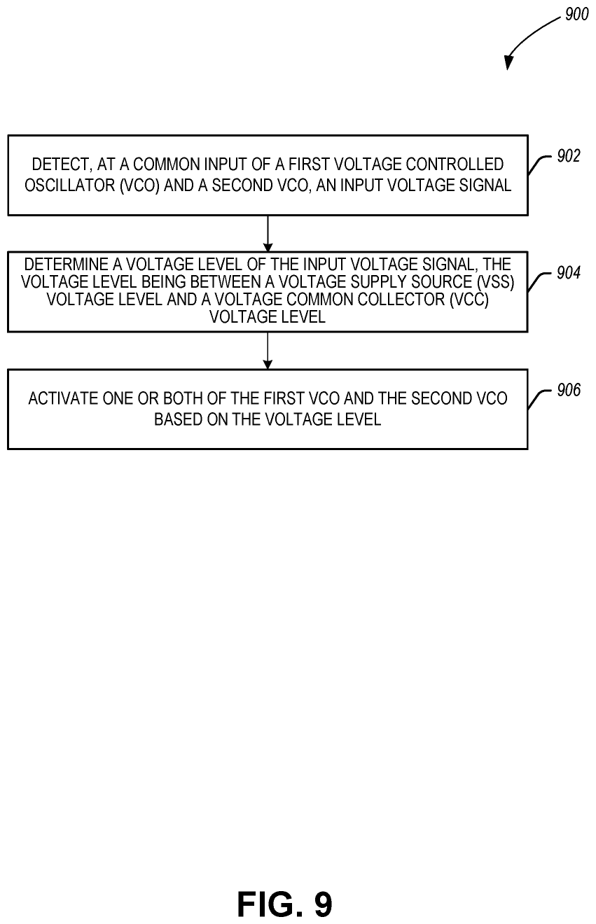

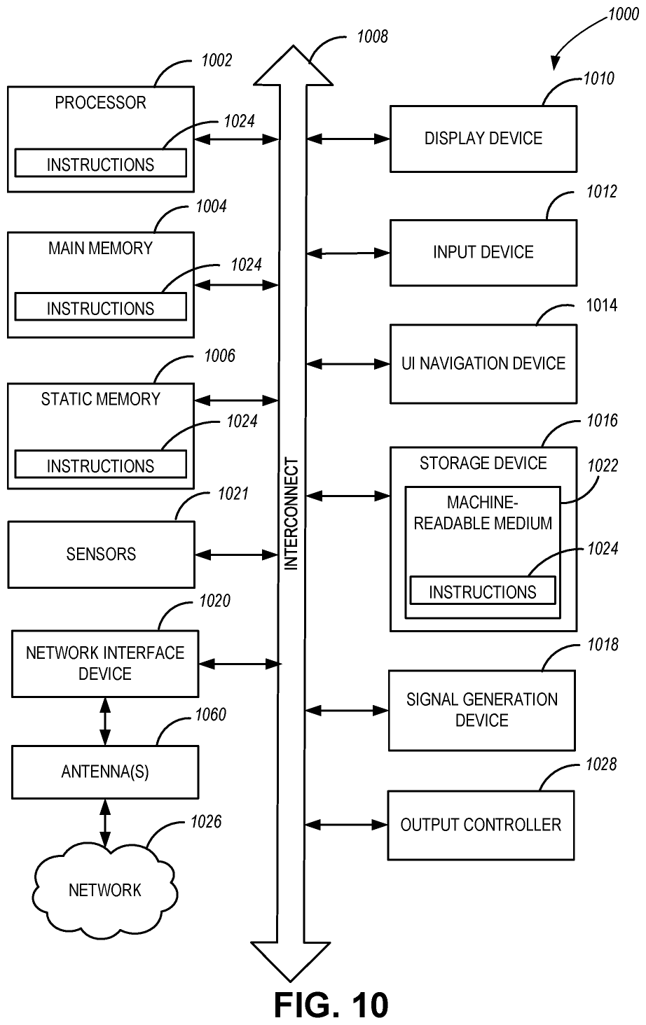

FIG. 9 is a flow diagram of an example method 900 for analog-to-digital conversion, in accordance with some embodiments. Referring to FIG. 9, method 900 includes operations 902, 904, and 906, which may be executed by a processor of a computing device (e.g., hardware processor 1002 of device 1000 illustrated in FIG. 10).

At operation 902, an input voltage signal (e.g., the input voltage signal 401) is detected at a common input of a first voltage-controlled oscillator (VCO) (e.g., oscillator 402) and a second VCO (e.g., oscillator 404).

At operation 904, the voltage level of the input voltage signal is determined. The voltage level can be between a voltage supply source (Vss) voltage level and a voltage common collector (Vcc) voltage level.

At operation 906, one or both of the first VCO and the second VCO are activated based on the voltage level. In some aspects, both the first VCO and the second VCO receive the input voltage signal and each is activated (or not activated) based on the level of PMOS and NMOS bias voltages generated by the biasing circuit of each oscillator.

FIG. 10 illustrates a block diagram of an example machine 1000 upon which any one or more of the techniques (e.g., methodologies) discussed herein may perform. In alternative embodiments, machine 1000 may operate as a standalone device or may be connected (e.g., networked) to other machines. In a networked deployment, machine 1000 may operate in the capacity of a server machine, a client machine, or both in server-client network environments. In an example, machine 1000 may act as a peer machine in a peer-to-peer (P2P) (or other distributed) network environment. The Machine 1000 may be a personal computer (PC), a tablet PC, a set-top box (STB), a personal digital assistant (PDA), a portable communications device, a mobile telephone, a smartphone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Machine (e.g., computer system) 1000 may include a hardware processor 1002 (e.g., a central processing unit (CPU), a graphics processing unit (GPU), a hardware processor core, or any combination thereof), a main memory 1004, and a static memory 1006, some or all of which may communicate with each other via an interlink (e.g., bus) 1008. In some aspects, the main memory 1004, the static memory 1006, or any other type of memory (including cache memory) used by the machine 1000 can be configured based on the disclosed techniques or can implement the disclosed memory devices.

Specific examples of main memory 1004 include Random Access Memory (RAM), and semiconductor memory devices, which may include, in some embodiments, storage locations in semiconductors such as registers. Specific examples of static memory 1006 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1000 may further include a display device 1010, an input device 1012 (e.g., a keyboard), and a user interface (UI) navigation device 1014 (e.g., a mouse). In an example, the display device 1010, input device 1012, and UI navigation device 1014 may be a touch screen display. The machine 1000 may additionally include a storage device (e.g., drive unit or another mass storage device) 1016, a signal generation device 1018 (e.g., a speaker), a network interface device 1020, and one or more sensors 1021, such as a global positioning system (GPS) sensor, compass, accelerometer, or other sensors. The machine 1000 may include an output controller 1028, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the processor 1002 and/or instructions 1024 may comprise processing circuitry and/or transceiver circuitry.

The storage device 1016 may include a machine-readable medium 1022 on which is stored one or more sets of data structures or instructions 1024 (e.g., software) embodying or utilized by any one or more of the techniques or functions described herein. The instructions 1024 may also reside, completely or at least partially, within the main memory 1004, within static memory 1006, or the hardware processor 1002 during execution thereof by the machine 1000. In an example, one or any combination of the hardware processor 1002, the main memory 1004, the static memory 1006, or the storage device 1016 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1022 is illustrated as a single medium, the term “machine-readable medium” may include a single medium or multiple media (e.g., a centralized or distributed database, and/or associated caches and servers) configured to store instructions 1024.

An apparatus of the machine 1000 may be one or more of a hardware processor 1002 (e.g., a central processing unit (CPU), a graphics processing unit (GPU), a hardware processor core, or any combination thereof), a main memory 1004 and a static memory 1006, one or more sensors 1021, a network interface device 1020, one or more antennas 1060, a display device 1010, an input device 1012, a UI navigation device 1014, a storage device 1016, instructions 1024, a signal generation device 1018, and an output controller 1028. The apparatus may be configured to perform one or more of the methods and/or operations disclosed herein. The apparatus may be intended as a component of machine 1000 to perform one or more of the methods and/or operations disclosed herein, and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1000 and that causes the machine 1000 to perform any one or more of the techniques of the present disclosure, or that is capable of storing, encoding or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1024 may further be transmitted or received over a communications network 1026 using a transmission medium via the network interface device 1020 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 1020 may include one or more physical jacks (e.g., Ethernet, coaxial, or phone jacks) or one or more antennas to connect to the communications network 1026. In an example, the network interface device 1020 may include one or more antennas 1060 to wirelessly communicate using at least one single-input multiple-output (SIMO), multiple-input multiple-output (MIMO), or multiple-input single-output (MISO) techniques. In some examples, the network interface device 1020 may wirelessly communicate using Multiple User MIMO techniques. The term “transmission medium” shall be taken to include any intangible medium that is capable of storing, encoding, or carrying instructions for execution by the machine 1000, and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a certain manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at different times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM); random access memory (RAM); magnetic disk storage media; optical storage media; flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments such as part of a wireless local area network (WLAN), 3rd Generation Partnership Project (3GPP) Universal Terrestrial Radio Access Network (UTRAN), or Long-Term-Evolution (LTE) or a Long-Term-Evolution (LTE) communication system, although the scope of the disclosure is not limited in this respect.

Antennas referred to herein may comprise one or more directional or omnidirectional antennas, including, for example, dipole antennas, monopole antennas, patch antennas, loop antennas, microstrip antennas, or other types of antennas suitable for transmission of RF signals. In some embodiments, instead of two or more antennas, a single antenna with multiple apertures may be used. In these embodiments, each aperture may be considered a separate antenna. In some multiple-input multiple-output (MIMO) embodiments, antennas may be effectively separated to take advantage of spatial diversity and the different channel characteristics that may result between each antenna and the antennas of a transmitting station. In some MIMO embodiments, antennas may be separated by up to 1/10 of a wavelength or more.

Described implementations of the subject matter can include one or more features, alone or in combination as illustrated below by way of examples.
Example 1 is an apparatus comprising: a first biasing circuit comprising: a first input stage comprising a plurality of serially coupled N-type metal-oxide semiconductor (NMOS) transistors, the plurality of serially coupled NMOS transistors comprising a corresponding plurality of gate terminals configured to receive an input voltage signal; and a first mirroring stage comprising a plurality of P-type metal-oxide semiconductor (PMOS) transistors, the plurality of PMOS transistors having corresponding source terminals coupled to a voltage common collector (Vcc) rail and configured to generate a first PMOS bias voltage based on the input voltage signal; and a second biasing circuit comprising: a second input stage comprising a plurality of serially coupled PMOS transistors, the plurality of serially coupled PMOS transistors comprising a corresponding plurality of gate terminals configured to receive the input voltage signal; and a second mirroring stage comprising a plurality of NMOS transistors, the plurality of PMOS transistors having corresponding drain terminals coupled to a voltage supply source (Vss) rail and configured to generate a first NMOS bias voltage based on the input voltage signal.
In Example 2, the subject matter of Example 1 includes subject matter where the plurality of PMOS transistors of the first mirroring stage comprise a first PMOS transistor and a second PMOS transistor, the first PMOS transistor and the second PMOS transistor of the first mirroring stage having commonly coupled gate terminals.
In Example 3, the subject matter of Examples 1-2 includes subject matter where one of the plurality of PMOS transistors of the first mirroring stage comprises a drain terminal coupled to a source terminal of one of the plurality of serially coupled NMOS transistors of the first input stage.
In Example 4, the subject matter of Examples 1-3 includes, an NMOS biasing transistor, the NMOS biasing transistor comprising a drain terminal coupled to the first input stage.
In Example 5, the subject matter of Example 4 includes subject matter where the NMOS biasing transistor comprises a source terminal coupled to the first mirroring stage.
In Example 6, the subject matter of Examples 4-5 includes subject matter where the NMOS biasing transistor is configured to generate a second NMOS bias voltage based on the input voltage signal.
In Example 7, the subject matter of Examples 1-6 includes subject matter where the plurality of NMOS transistors of the second mirroring stage comprise a first NMOS transistor and a second NMOS transistor, the first NMOS transistor and the second NMOS transistor of the second mirroring stage having commonly coupled gate terminals.
In Example 8, the subject matter of Examples 1-7 includes subject matter where one of the plurality of NMOS transistors of the second mirroring stage comprises a source terminal coupled to a drain terminal of one of the plurality of serially coupled PMOS transistors of the second input stage.
In Example 9, the subject matter of Examples 1-8 includes, a PMOS biasing transistor, the PMOS biasing transistor comprising a source terminal coupled to the Vcc rail and the second input stage.
In Example 10, the subject matter of Example 9 includes subject matter where the PMOS biasing transistor comprises a drain terminal coupled to the second mirroring stage.
In Example 11, the subject matter of Examples 9-10 includes subject matter where the PMOS biasing transistor is configured to generate a second PMOS bias voltage based on the input voltage signal.
In Example 12, the subject matter of Examples 1-11 includes, a first oscillator circuit coupled to the first biasing circuit; and a second oscillator circuit coupled to the second biasing circuit.
In Example 13, the subject matter of Example 12 includes subject matter where the first oscillator circuit comprises a first plurality of serially coupled inverters, and wherein the second oscillator circuit comprises a second plurality of serially coupled inverters.
In Example 14, the subject matter of Example 13 includes subject matter where the first oscillator circuit further comprises a corresponding plurality of PMOS transistors receiving the first PMOS bias voltage.
In Example 15, the subject matter of Example 14 includes subject matter where the second oscillator circuit further comprises a corresponding plurality of NMOS transistors receiving the first NMOS bias voltage.
In Example 16, the subject matter of Examples 12-15 includes subject matter where the first oscillator circuit generates a first output frequency signal based on the input voltage signal, and the second oscillator circuit generates a second output frequency signal based on the input voltage signal.
In Example 17, the subject matter of Examples 12-16 includes subject matter where when the input voltage signal is at a Vss voltage level of the Vss rail or within a first threshold voltage from the Vss voltage level, the first oscillator circuit is turned OFF and the second oscillator circuit is turned ON.
In Example 18, the subject matter of Example 17 includes subject matter where when the input voltage signal is at a Vcc voltage level of the Vcc rail or within a second threshold voltage from the Vcc voltage level, the first oscillator circuit is turned ON and the second oscillator circuit is turned OFF.
In Example 19, the subject matter of Example 18 includes subject matter where when the input voltage signal is between the first threshold voltage from the Vss voltage level and the second threshold voltage from the Vcc voltage level, the first oscillator circuit is turned ON and the second oscillator circuit is turned ON.
In Example 20, the subject matter of Examples 1-19 includes subject matter where the apparatus comprises one or more interfaces coupled to the first biasing circuit and the second biasing circuit.
In Example 21, the subject matter of Examples 1-20 includes subject matter where the apparatus comprises one or more interconnects coupling the first biasing circuit and the second biasing circuit.
In Example 22, the subject matter of Examples 1-21 includes subject matter where the apparatus comprises a processor, and wherein the processor includes the first biasing circuit and the second biasing circuit.
Example 23 is an apparatus comprising: a pair of voltage controlled oscillators (VCOs), the pair comprising: a first voltage controlled oscillator (VCO), the first VCO comprising a first biasing stage receiving an input voltage signal, and a first output stage coupled to the first biasing stage, the first output stage generating a first output frequency signal based on the input voltage signal; and a second VCO, the second VCO comprising a second biasing stage receiving the input voltage signal, and a second output stage coupled to the second biasing stage, the second output stage generating a second output frequency signal based on the input voltage signal.
In Example 24, the subject matter of Example 23 includes subject matter where the first VCO and the second VCO are coupled to a voltage supply source (Vss) rail associated with a first voltage level and voltage common collector (Vcc) rail associated with a second voltage level.
In Example 25, the subject matter of Example 24 includes subject matter where the pair of VCOs are configured to operate when the input voltage signal is above the first voltage level and below the second voltage level.
In Example 26, the subject matter of Examples 24-25 includes subject matter where the first VCO and the second VCO are configured to operate when the input voltage signal is between a first threshold voltage from the first voltage level and a second threshold voltage from the second voltage level.
In Example 27, the subject matter of Example 26 includes subject matter where the first VCO is activated and the second VCO is deactivated when the input voltage signal is below the first threshold voltage.
In Example 28, the subject matter of Example 27 includes subject matter where the second VCO is activated and the first VCO is deactivated when the input voltage signal is above the second threshold voltage.
In Example 29, the subject matter of Examples 23-28 includes, a counter circuit coupled to the first VCO and the second VCO, the counter circuit to receive the first output frequency signal and the second output frequency signal, and generate a digital output signal based on the first output frequency signal and the second output frequency signal.
In Example 30, the subject matter of Examples 23-29 includes subject matter where the apparatus comprises one or more interfaces coupled to the first VCO and the second VCO.
In Example 31, the subject matter of Examples 1-30 includes subject matter where the apparatus comprises one or more interconnects coupling the first VCO and the second VCO.
In Example 32, the subject matter of Examples 1-31 includes subject matter where the apparatus comprises a processor, and wherein the processor includes the first VCO and the second VCO.
Example 33 is a method comprising: detecting, at a common input of a first voltage controlled oscillator (VCO) and a second VCO, an input voltage signal; determining a voltage level of the input voltage signal, the voltage level being greater than or equal a voltage supply source (Vss) voltage level and smaller than or equal a voltage common collector (Vcc) voltage level; and activating one or both of the first VCO and the second VCO based on the voltage level.
In Example 34, the subject matter of Example 33 includes, activating the first VCO and deactivating the second VCO when the voltage level of the input voltage signal is below a first threshold voltage from the Vss voltage level.
In Example 35, the subject matter of Example 34 includes, deactivating the first VCO and activating the second VCO when the voltage level of the input voltage signal is above a second threshold voltage from the Vcc voltage level.
In Example 36, the subject matter of Example 35 includes, activating the first VCO and the second VCO when the voltage level of the input voltage signal is between the first threshold voltage and the second threshold voltage.
In Example 37, the subject matter of Examples 33-36 includes subject matter wherein the first VCO is a high-bias VCO and the second VCO is a low-bias VCO.
In Example 38, the subject matter of Examples 33-37 includes, generating one or both of a first output frequency signal using the first VCO and a second output frequency signal using the second VCO based on the activating.
In Example 39, the subject matter of Example 38 includes, generating a digital signal output based on one or both of the first output frequency signal and the second output frequency signal.
Example 40 is at least one machine-readable medium including instructions that, when executed by processing circuitry, cause the processing circuitry to perform operations to implement of any of Examples 1-39.
Example 41 is an apparatus comprising means to implement of any of Examples 1-39.
Example 42 is a system to implement of any of Examples 1-39.
Example 43 is a method to implement of any of Examples 1-39.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a first biasing circuit comprising:
a first input stage comprising a plurality of serially coupled N-type metal-oxide semiconductor (NMOS) transistors, the plurality of serially coupled NMOS transistors comprising a corresponding plurality of gate terminals configured to receive an input voltage signal; and
a first mirroring stage comprising a plurality of P-type metal-oxide semiconductor (PMOS) transistors, the plurality of PMOS transistors having corresponding source terminals coupled to a voltage common collector (Vcc) rail and configured to generate a first PMOS bias voltage based on the input voltage signal; and
a second biasing circuit comprising:
a second input stage comprising a plurality of serially coupled PMOS transistors, the plurality of serially coupled PMOS transistors comprising a corresponding plurality of gate terminals configured to receive the input voltage signal; and
a second mirroring stage comprising a plurality of NMOS transistors, the plurality of PMOS transistors having corresponding drain terminals coupled to a voltage supply source (Vss) rail and configured to generate a first NMOS bias voltage based on the input voltage signal.

2. The apparatus of claim 1, wherein the plurality of PMOS transistors of the first mirroring stage comprise a first PMOS transistor and a second PMOS transistor, the first PMOS transistor and the second PMOS transistor of the first mirroring stage having commonly coupled gate terminals.

3. The apparatus of claim 1, wherein one of the plurality of PMOS transistors of the first mirroring stage comprises a drain terminal coupled to a source terminal of one of the plurality of serially coupled NMOS transistors of the first input stage.

4. The apparatus of claim 1, further comprising:
an NMOS biasing transistor, the NMOS biasing transistor comprising a drain terminal coupled to the first input stage.

5. The apparatus of claim 4, wherein the NMOS biasing transistor comprises a source terminal coupled to the first mirroring stage.

6. The apparatus of claim 4, wherein the NMOS biasing transistor is configured to generate a second NMOS bias voltage based on the input voltage signal.

7. The apparatus of claim 1, wherein the plurality of NMOS transistors of the second mirroring stage comprise a first NMOS transistor and a second NMOS transistor, the first NMOS transistor and the second NMOS transistor of the second mirroring stage having commonly coupled gate terminals.

8. The apparatus of claim 1, wherein one of the plurality of NMOS transistors of the second mirroring stage comprises a source terminal coupled to a drain terminal of one of the plurality of serially coupled PMOS transistors of the second input stage.

9. The apparatus of claim 1, further comprising:
a PMOS biasing transistor, the PMOS biasing transistor comprising a source terminal coupled to the Vcc rail and the second input stage.

10. The apparatus of claim 1, wherein the apparatus comprises one or more interfaces coupled to the first biasing circuit and the second biasing circuit.

11. The apparatus of claim 1, wherein the apparatus comprises one or more interconnects coupling the first biasing circuit and the second biasing circuit.

12. The apparatus of claim 1, wherein the apparatus comprises a processor, and wherein the processor includes the first biasing circuit and the second biasing circuit.

13. An apparatus comprising:
a pair of voltage controlled oscillators (VCOs), the pair comprising:
a first voltage controlled oscillator (VCO), the first VCO comprising a first biasing stage receiving an input voltage signal, and a first output stage coupled to the first biasing stage, the first output stage generating a first output frequency signal based on the input voltage signal; and
a second VCO, the second VCO comprising a second biasing stage receiving the input voltage signal, and a second output stage coupled to the second biasing stage, the second output stage generating a second output frequency signal based on the input voltage signal.

14. The apparatus of claim 13, wherein the first VCO and the second VCO are coupled to a voltage supply source (Vss) rail associated with a first voltage level and voltage common collector (Vcc) rail associated with a second voltage level.

15. The apparatus of claim 14, wherein the pair of VCOs are configured to operate when the input voltage signal is above the first voltage level and below the second voltage level.

16. The apparatus of claim 14, wherein the first VCO and the second VCO are configured to operate when the input voltage signal is between a first threshold voltage from the first voltage level and a second threshold voltage from the second voltage level.

17. The apparatus of claim 16, wherein the first VCO is activated and the second VCO is deactivated when the input voltage signal is below the first threshold voltage.

18. The apparatus of claim 17, wherein the second VCO is activated and the first VCO is deactivated when the input voltage signal is above the second threshold voltage.

19. A method comprising:
detecting, at a common input of a first voltage controlled oscillator (VCO) and a second VCO, an input voltage signal;
determining a voltage level of the input voltage signal, the voltage level being greater than or equal a voltage supply source (Vss) voltage level and smaller than or equal a voltage common collector (Vcc) voltage level; and
activating one or both of the first VCO and the second VCO based on the voltage level.

20. The method of claim 19, further comprising:
activating the first VCO and deactivating the second VCO when the voltage level of the input voltage signal is below a first threshold voltage from the Vss voltage level;
deactivating the first VCO and activating the second VCO when the voltage level of the input voltage signal is above a second threshold voltage from the Vcc voltage level; and
activating the first VCO and the second VCO when the voltage level of the input voltage signal is between the first threshold voltage and the second threshold voltage.
